(19) United States
(12) Patent Application Publication
(10) Pub. No.: US 2012/0181501 A1
(43) Pub. Date: Jul. 19, 2012

(54) Graphene on Diamond Devices and Associated Methods

(76) Inventor: Chien-Min Sung, Tansui (TW)

(21) Appl. No.: 13/343,155

(22) Filed: Jan. 4, 2012

Related U.S. Application Data
(60) Provisional application No. 61/432,435, filed on Jan. 13, 2011.

(51) Int. Cl. H01L 29/02; B32B 9/04; C30B 1/04; C30B 1/10; B82Y 99/00

(52) U.S. Cl. 257/9; 117/9; 117/7; 428/408; 257/E29.002; 977/734

(57) ABSTRACT

Graphene layers and associated methods are disclosed. In one aspect, for example, a method of making graphene on a diamond substrate is provided. Such a method can include applying a layer of a metal to a crystallographic face of the diamond substrate, and heating the diamond substrate under vacuum to convert a portion of the diamond substrate at the crystallographic face into graphene. In another aspect, the layer of metal is applied only on diamond substrate faces having a same crystallographic orientation. In yet another aspect, the layer of metal is applied to only a single crystallographic face of the diamond substrate. Additionally, in one aspect, converting the portion of the diamond substrate at the crystallographic face into graphene includes converting the portion of the diamond substrate by a martensitic transformation.

### PRIORITY DATA

This application claims the benefit of U.S. Provisional Patent Application Ser. No. 61/432,435, filed on Jan. 13, 2011, which is incorporated herein by reference.

### FIELD OF THE INVENTION

The present invention relates generally to the formation of graphene on diamond surfaces and associated methods. Accordingly, the present invention involves the chemical and material science fields.

### BACKGROUND OF THE INVENTION

Graphene is a one-atom-thick planar sheet of sp2-bonded carbon atoms that are densely packed into a benzene-ring structure in a honeycomb crystal lattice. This two-dimensional material exhibits high electron mobility in the plane of the layer, as well as exceptional thermal conductivity. Graphite is comprised of multiple layers of graphene stacked parallel to one another.

Graphene is widely used to describe properties of many carbon-based materials, including graphite, large fullerenes, nanotubes, etc. For example, carbon nanotubes may be described as graphene sheets rolled up into nanometer-sized cylinders. Furthermore, planar graphene itself has been presumed not to exist in the free state, being unstable with respect to the formation of curved structures such as soot, fullerenes, and nanotubes.

Attempts have been made to incorporate graphene into electronic devices such as transistors, however such attempts have generally been unsuccessful due to problems associated with the production of high quality graphene layers of a size suitable for incorporation into such devices. One technique for generating graphene layers involves peeling graphene planes from highly oriented pyrolific graphite. Using such methods, only small flakes are produced that are generally too small to be utilized in electronic applications.

### SUMMARY OF THE INVENTION

Accordingly, the present invention provides diamond devices incorporating graphene materials, graphene materials, and associated methods. In one aspect, for example, a method of making graphene on a diamond substrate is provided. Such a method can include applying a layer of a metal to a crystallographic face of the diamond substrate, and heating the diamond substrate under vacuum to convert a portion of the diamond substrate at the crystallographic face into graphene. In another aspect, the layer of metal is applied only on diamond substrate faces having a same crystallographic orientation. In yet another aspect, the layer of metal is applied to only a single crystallographic face of the diamond substrate. In a further aspect, the crystallographic face is a (111) face. Additionally, in one aspect, converting the portion of the diamond substrate at the crystallographic face into graphene includes converting the portion of the diamond substrate by a martensitic transformation. In another aspect, the diamond substrate is nanodiamond.

A variety of metal materials are contemplated, and any such metal capable of facilitating the formation of graphene from carbon atoms in a diamond surface is considered to be within the present scope. In one aspect, for example, the metal can be a metal alloy. Non-limiting examples of metals that can be used in the metal alloy include Fe, Ni, Co, and the like, including combinations thereof. Non-limiting examples of metals that can be alloyed therewith include Cu, Zn, and the like, including combinations thereof.

Processing conditions can vary depending on various factors such as the nature of the diamond substrate, the desired composition of the graphene material, and the like. As such, any process conditions capable of producing graphene on the diamond substrate according to aspects of the present invention are considered to be within the present scope. That being said, in one aspect, the diamond substrate is heated to a temperature of between about 600° C. and about 1400° C. In another aspect, the vacuum is from about 10⁻⁴ torr to about 10⁻⁶ torr.

The graphene material can be utilized alone or in connection with the diamond substrate. Accordingly, in one aspect, the method can include removing the graphene from the diamond substrate. In another aspect the graphene material can remain coupled to the diamond substrate to be used as an integrated diamond-graphene device. In one aspect, for example, a semiconductor material can be deposited on the graphene material. In one specific aspect, the semiconductor material is deposited epitaxially on the graphene.

Various devices can benefit from a corresponding relationship between the crystal lattice of the diamond substrate and the graphene material lattice. In one aspect, for example, an epitaxial relationship is maintained between the diamond substrate and the graphene. In one specific aspect, the diamond substrate and the graphene material are heated to a temperature of greater than or equal to about 700° C. in a hydrogen atmosphere to gasify non-epitaxial carbon atoms.

The present invention additionally provides diamond-graphene devices. Such a device can include a diamond substrate and a graphene material formed on and epitaxially aligned with a crystallographic surface of the diamond substrate. The graphene material is oriented such that substantially all graphene planes are parallel to the crystallographic surface. Additionally, in one aspect the graphene material has been formed from a portion of the diamond substrate. In another aspect, the graphene material has been formed on a (111) face of the diamond substrate.

A variety of uses are contemplated for the diamond-graphene devices according to aspects of the present invention. For example, in one aspect a semiconductor material is disposed on the graphene material. Such a substrate can be useful in a variety of devices, including various electronics. One specific example is an LED substrate. Other examples include molecule sensors, LCDs, solar panels, pressure sensors, SAW filters, resonators, and the like.

Depending on the desired use of the semiconductor device, any semiconductor material can be used. Non-limiting examples of semiconductor materials can include silicon, silicon carbide, silicon germanium, gallium arsenide, gallium nitride, germanium, zinc sulfide, gallium phosphide, gallium antimonide, gallium indium arsenide phosphide, aluminum phosphide, aluminum arsenide, aluminum gallium arsenide, gallium nitride, boron nitride, aluminum nitride, indium arsenide, indium phosphide, indium antimonide, indium nitride, and the like, including composites thereof. In one specific aspect, the semiconductor material can include gallium nitride, aluminum nitride, indium nitride, and composites thereof. In another specific aspect, the semiconductor material can include gallium nitride.

There has thus been outlined, rather broadly, various features of the invention so that the detailed description thereof that follows may be better understood, and so that the present contribution to the art may be better appreciated. Other features of the present invention will become clearer from the following detailed description of the invention, taken with the accompanying claims, or may be learned by the practice of the invention.

### BRIEF DESCRIPTION OF THE DRAWINGS

FIG. 1 is a graphical representation of a graphene lattice in accordance with one embodiment of the present invention.

FIG. 2 is a cross-sectional view of a graphene on diamond device in accordance with another embodiment of the present invention.

FIG. 3 is a cross-sectional view of a graphene on diamond device in accordance with yet another embodiment of the present invention.

### DETAILED DESCRIPTION OF THE INVENTION

### Definitions

In describing and claiming the present invention, the following terminology will be used in accordance with the definitions set forth below.

The singular forms “a,” “an,” and, “the” include plural referents unless the context clearly dictates otherwise. Thus, for example, reference to “a particle” includes reference to one or more of such particles, and reference to “the material” includes reference to one or more of such materials.

As used herein, the term “substantially” refers to the complete or nearly complete extent or degree of an action, characteristic, property, state, structure, item, or result. For example, an object that is “substantially” enclosed would mean that the object is either completely enclosed or nearly completely enclosed. The exact allowable degree of deviation from absolute completeness may in some cases depend on the specific context. However, generally speaking the nearness of completion will be so as to have the same overall result as if absolute and total completion were obtained. The use of “substantially” is equally applicable when used in a negative connotation to refer to the complete or near complete lack of an action, characteristic, property, state, structure, item, or result. For example, a composition that is “substantially free of” particles would either completely lack particles, or so nearly completely lack particles that the effect would be the same as if it completely lacked particles. In other words, a composition that is “substantially free of” an ingredient or element may still actually contain such item as long as there is no measurable effect thereof.

As used herein, the term “about” is used to provide flexibility to a numerical range endpoint by providing that a given value may be “a little above” or “a little below” the endpoint.

As used herein, a plurality of items, structural elements, compositional elements, and/or materials may be presented in a common list for convenience. However, these lists should be construed as though each member of the list is individually identified as a separate and unique member. Thus, no individual member of such list should be construed as a de facto equivalent of any other member of the same list solely based on their presentation in a common group without indications to the contrary.

Concentrations, amounts, and other numerical data may be expressed or presented herein in a range format. It is to be understood that such a range format is used merely for convenience and brevity and thus should be interpreted flexibly to include not only the numerical values explicitly recited as the limits of the range, but also to include all the individual numerical values or sub-ranges encompassed within that range as if each numerical value and sub-range is explicitly recited. As an illustration, a numerical range of “about 1 to about 5” should be interpreted to include not only the explicitly recited values of about 1 to about 5, but also include individual values and sub-ranges within the indicated range. Thus, included in this numerical range are individual values such as 2, 3, and 4 and sub-ranges such as from 1-3, from 2-4, and from 3-5, etc., as well as 1, 2, 3, 4, and 5, individually. This same principle applies to ranges reciting only one numerical value as a minimum or a maximum. Furthermore, such an interpretation should apply regardless of the breadth of the range or the characteristics being described.

### THE INVENTION

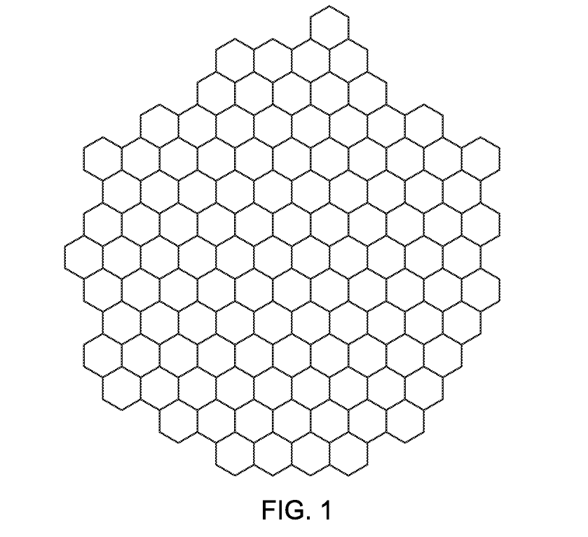

The present disclosure relates to novel diamond-graphene devices, graphene materials, and associated methods. The inventor has discovered a process for converting a portion of a diamond substrate to graphene. Graphene is a one-atom-thick planar sheet of sp2-bonded carbon atoms that are densely packed into a carbon-ring structure in a honeycomb crystal lattice, as is shown in FIG. 1. The carbon-carbon bond length in graphene is approximately 1.45 Å, which is shorter than that of diamond at 1.54 Å. Graphene is the basic structural element of other graphitic materials including graphite, carbon nanotubes, fullerenes, etc. It should be noted that the term “graphene” as is used herein includes reference to both single atom layers of graphene and multiple layer stacks of graphene.

Perfect graphene planes consist exclusively of hexagonal cells, and any pentagonal or heptagonal cells within a graphene plane would constitute “defects” that alter the planar nature of the graphene layer. For example, an isolated pentagonal cell warps the plane into a cone shape, while 12 pentagons at the proper locations would create a fullerene of the plane. Also, an isolated heptagon warps the plane into a saddle-shape. Warpage of the graphene plane tends to reduce electron mobility and thermal conductivity, and thus may be undesirable for some applications where these properties are desired.

The physical characteristics of graphene layers can make it a beneficial material to incorporate into a variety of devices. Numerous devices and uses are contemplated, and the following examples should not be seen as limiting. For example, in one aspect, the high electron mobility of graphene can make it a useful component of integrated circuits. Such a material would allow the formation of thin, intricate integrated circuit elements having beneficial electrical properties. In another aspect, graphene can be used as a sensor for single or multiple molecule detection, including gasses. The 2D structure of a graphene layer effectively exposes the entire volume of the graphene material to a surrounding environment, thus making it an efficient material for the detection of molecules. Such molecule detection can be measured indirectly because, as a gas or other molecule adsorbs to the surface of graphene, the location of absorption will experience a detectable local change in electrical resistance. Graphene is a useful material for such detection due to its high electrical conductivity and low noise. In another aspect, a graphene layer can be utilized as a surface acoustic wave (SAW) filter. In this case, a voltage signal can be transmitted due to the resonance of the graphene material. In yet another aspect, graphene may be utilized as a pressure sensor. As the graphene lattice is deflected under pressure, electrical resistance changes can be detected to allow a measurement of such pressure. In a further aspect, graphene layers may be utilized as transparent electrodes for LED, LCD, and solar panel applications.

As has been described, the present process converts a portion of a diamond substrate into graphene. In one aspect, graphene can be formed on the (111) crystallographic face of the diamond substrate. Graphene can be thought of as a flattened diamond (111) face or, alternatively, that a diamond (111) face is puckered (or nonplanar) graphene. While single layers of graphene are generally defined as being planar, multiple layers are commonly nonplanar. In the case of hexagonal graphite (the dominant form of ordinary graphite), every other carbon atom in each graphene layer is linked to adjacent layers, and the non-linked carbon atoms are offset from the carbon hexagons of adjacent layers. As a result, the graphene (or graphite) surface is puckered due to bonding atoms that are slightly closer to each other due to van der Waals forces, although to a lesser degree than the (111) face of diamond.

In the case of rhombohedral graphite, the ABC layers are offset similar to cubic diamond. In other words, rhombohedral graphite can be thought of as stretched cubic diamond, and cubic diamond can be thought of as puckered rhombohedral graphite. By heating a diamond substrate under vacuum, a portion of the diamond surface can convert into graphene material. Without intending to be bound to any particular scientific theory, the diamond material may transform to graphene via a martensitic transformation. This transformation can be rapid, as martensitic transformation involves the displacement rather than the diffusion of atoms.

In some cases, graphene layers lacking grain boundaries can be difficult to produce, particularly as the size of the diamond substrate increases. To overcome such difficulties, the diamond substrate can be transformed to graphene in a sequential manner that proceeds layer by layer in such a way that an epitaxial relationship is maintained between the diamond and the graphene materials. Such a sequential transformation can be accomplished by coating the diamond surface to be transformed with a metal, such as a metal alloy. A metal alloy, and in particular a metal alloy containing Fe, Ni, and/or Co, is capable of converting graphene (or graphite) to diamond under high pressure and diamond to graphene under low pressure. Without intending to be bound to any particular theory, it appears that this transformation is accomplished due to the atomic size of the metal atoms relative to the size of carbon atoms in the diamond/graphene. The vacant d-orbitals of the metal atoms attract p-electrons on carbon atoms, and thus the metal atoms can selectively attract every other carbon atom on graphene under high pressure to cause the material to pucker, thus forming a diamond material. The same attraction process occurs under low pressure to relax and flatten the diamond material into graphene in a sequential manner.

In some cases, the transformation can be moderated by the metal alloy's composition and/or thickness, as well as the temperature and vacuum conditions in the furnace. For example, if Fe alone is used, cementite (iron carbide) may form due to the reactivity of Fe and disrupt the graphene lattice. Cu and Zi, on the other hand, are less reactive as these atoms do not have empty d-orbitals and would not attract carbon atoms. Thus these materials in the metal alloy can moderate the reactivity of the other alloy constituents. Thus an alloy of Ni—Cu, for example, can moderate the reactivity and thus the attractive force between the metal and carbon atoms. In this way, the transformation can be controlled in such a way as to only allow the surface layers (e.g. 100 layers or about 30 nm thick) of the diamond surface to be affected. Thus if the transformation is controlled in such a manner, the diamond lattice will gradually relax or phase into the graphene lattice.

It is also contemplated that graphene can be formed on the (100) face of the diamond substrate. This can be accomplished by heating the diamond substrate under vacuum in a hydrogen atmosphere. Such graphene growth can be accomplished without a metal alloy coating. The graphene planes will grow in this case in an orientation that is perpendicular to the (100) diamond surface.

Various diamond materials are contemplated as diamond substrates, and any diamond materials capable of being converted to graphene by methods according to aspects of the present invention are considered to be within the present scope. For example, diamond substrates can include natural or synthetic diamonds, diamond-like carbon, amorphous diamond, polycrystalline diamond, and the like. Additionally, the sizes of diamond substrates can vary depending on the desired use of the graphene material. In one aspect, for example, the diamond substrate can be a nanodiamond particle. In other aspects, the diamond substrate can be microns, hundreds of microns, thousands of microns, or larger in size. In another aspect, diamond substrates can be from about 20 mesh to about 400 mesh.

The metal or metal alloy can be applied to various crystallographic faces of the diamond substrate, and the resulting graphene layer can vary depending on the facial orientation of the substrate. In one aspect, for example, the metal alloy can be applied to a (111) crystallographic face of the diamond substrate. Resulting graphene material will be oriented parallel to the surface of the diamond substrate, and be compatible with a wurtzite structure semiconductor. As has been described, graphene formed on the (100) face of the diamond substrate would have planes that are perpendicular to the diamond surface. It should be noted that the graphene can be formed on a single crystallographic face, multiple crystallographic faces of the same orientation, or on crystallographic faces of different orientations.

As has been described, a metal material such as a metal alloy applied to the diamond substrate can allow transformation of a portion of the diamond material into graphene. In one aspect, one component of the metal alloy interacts with the diamond surface to relax the puckered diamond into a graphene state, while another component of the metal alloy moderates the reactivity of the first component. The first metal alloy component can include any metal material capable of interacting with diamond to generate graphene by martensitic transformation. Non-limiting examples of such materials can include Fe, Ni, Co, and the like, including combinations thereof. The second component can include any metal material capable of moderating the reactivity of the first metal alloy component. Non-limiting examples include Cu, Zn, and the like, including combinations thereof. One specific non-limiting example includes Ni—Cu.

The diamond substrate and the metal alloy are heated under vacuum to a temperature that allows the transition of the diamond material into graphene. The temperature at which such a transformation occurs can vary due to the metal alloy materials, the thickness of the metal alloy, the size of the diamond substrate, and the like. That being said, one of ordinary skill in the art would be capable of fine tuning the temperature and pressure conditions to match a given set materials once in possession of the present specification. As a general guideline, however, the diamond substrate is heated to a temperature of between about 600° C. and about 1400° C. Additionally, the vacuum is from about 10⁻⁴ to about 10⁻⁶ torr.

In some aspects, it can be important to maintain an epitaxial relationship between the diamond substrate and the graphene. This may be particularly important for those applications where the diamond substrate and the graphene are incorporated into an electrical device such as an LED. An epitaxial relationship allows the transmission of heat and/or electrons from one material to the other or across the graphene material itself. A non-epitaxial relationship results in grain boundaries introduced into the graphene material that can impede movement there through. Various methods of backconversion can be utilized to maintain the epitaxy of the expanding graphene layers, and any such method is considered to be within the present scope. In one exemplary aspect, the diamond substrate and the growing graphene material can be subjected to high heat in the presence of hydrogen. In this way, non-epitaxial carbon atoms will be selectively gasified to become methane, thus removing them from the growing graphene. This selective gasification is due in part to the non-gasification of sp3 bonds. Thus in one aspect, the diamond substrate is heated to a temperature of greater than or equal to about 700° C. in a hydrogen atmosphere to gasify non-epitaxial carbon atoms.

Various further processing steps can be performed once the graphene material has been formed on the diamond substrate. For example, in one aspect the graphene can be removed from the substrate. In another aspect, the diamond substrate and the graphene can be utilized together as a substrate for further processing, such as, for example, incorporation into an electronic device. As such, a semiconductor material can be deposited on the graphene material. The semiconductor material can be deposited epitaxially or non-epitaxially on the graphene.

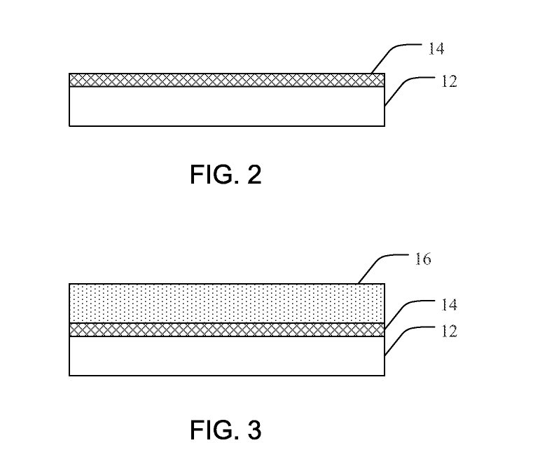

Accordingly, in one aspect a diamond-graphene device is provided, as is shown in FIG. 2. Such a device includes a diamond substrate 12, and a graphene material 14 formed on and epitaxially aligned with a crystallographic surface of the diamond substrate 12. The graphene material 14 is oriented such that substantially all graphene planes are parallel to the crystallographic surface of the diamond substrate 12. In a further aspect, as is shown in FIG. 3, a semiconductor material 16 is disposed on the graphene material 14.

The physical characteristics of graphene layers, particularly when epitaxially bonded to diamond, make it a beneficial material to incorporate into a variety of devices. Numerous devices and uses are contemplated, and the following examples should not be seen as limiting. For example, in one aspect, the high electron mobility of graphene makes it useful as a component of integrated circuits and various integrated circuit elements. In another aspect, graphene can be used as a sensor for single or multiple molecule detection, including gasses. The 2D structure of a graphene layer effectively exposes the entire volume of the graphene material to a surrounding environment, thus making it an efficient material for the detection of molecules. Such molecule detection can be measured indirectly: as a gas molecule adsorbs to the surface of graphene, the location of adsorption will experience a local change in electrical resistance. Graphene is a useful material for such detection due to its high electrical conductivity and low noise which makes this change in resistance detectable. In another aspect, a graphene layer may be utilized as a surface acoustic wave (SAW) filter. In this case a voltage signal can be transmitted due to the resonance of the graphene material. In yet another aspect, graphene may be utilized as a pressure sensor. In a further aspect, graphene layers may be utilized as transparent electrodes for LED, LCD, and solar panel applications.

Thus the graphene can allow a greater epitaxy between the thermal heat spreading diamond substrate and the electrically active semiconductor materials than has previously been possible. As one specific example, graphene formed on the (111) face of the diamond substrate is epitaxially compatible with the wurtzitic structure of nitride LEDs.

The graphene material is epitaxially bonded to the diamond substrate and also allows epitaxial deposition of GaN there upon. Thus forming a nitride LED (e.g. GaN) on the graphene material can result in an LED that has superior cooling properties due to the thermally integrated diamond substrate. Such an LED can be operated at higher operating temperatures and/or for longer periods of time without failure. A UV LED can also be formed by depositing (B, Al)N on the graphene with a bandgap of about 6 eV. In addition to LED devices, the diamond-graphene substrates can be incorporated into molecule sensors, LCDs, solar panels, pressure sensors, SAW filters, resonators, signal transmitters, signal receivers, and the like.

Various semiconductor materials can be deposited onto the graphene material, depending on the nature of the electronic device and the desired outcome. Non-limiting examples of semiconductor materials include silicon, silicon carbide, silicon germanium, gallium arsenide, gallium nitride, germanium, zinc sulfide, gallium phosphide, gallium antimonide, gallium indium arsenide phosphide, aluminum phosphide, aluminum arsenide, aluminum gallium arsenide, gallium nitride, boron nitride, aluminum nitride, indium arsenide, indium phosphide, indium antimonide, indium nitride, and composites thereof. In a more specific aspect, the semiconductor for material includes gallium nitride, aluminum nitride, indium nitride, and composites thereof. In some aspects, an hBN layer can be deposited onto the graphene layer. More information regarding graphene devices, as well as graphene/hBN devices can be found in U.S. patent application Ser. No. 12/955,505, filed on Nov. 29, 2010, and in U.S. Provisional Patent Application No. 61/298,458, filed on Jan. 26, 2010, both of which are incorporated herein by reference.

In some aspects of the present disclosure, graphene layers can be doped with a variety of dopants. Dopants can be utilized to alter the physical properties of a graphene layer, and/or they can be utilized to alter the physical interactions between graphene layers. Such doping can occur during formation of the graphene layer by adding the dopant to the metal alloy or diamond substrate, or it can occur following the formation of the graphene layer by depositing the dopant in the layer. By doping with boron, for example, a P-type semiconductor can be formed.

A variety of dopants can be utilized for doping the graphene layers. Specific non-limiting examples can include boron, phosphorous, nitrogen, and combinations thereof. Doping can also be utilized to alter the electron mobility of specific regions of the graphene layer for the formation of circuits within the layer. Such site specific doping can allow the patterning of electrical circuits within a layer of graphene. Furthermore, while graphene layers have a high electron mobility, conductivity between graphene layers in a stack is more limited. By doping with metal atoms or other conductive materials, the electron mobility between stacked layers can be increased.

Of course, it is to be understood that the above-described arrangements are only illustrative of the application of the principles of the present invention. Numerous modifications and alternative arrangements may be devised by those skilled in the art without departing from the spirit and scope of the present invention and the appended claims are intended to cover such modifications and arrangements. Thus, while the present invention has been described above with particularity and detail in connection with what is presently deemed to be the most practical and preferred embodiments of the invention, it will be apparent to those of ordinary skill in the art that numerous modifications, including, but not limited to, variations in size, materials, shape, form, function and manner of operation, assembly and use may be made without departing from the principles and concepts set forth herein.

What is claimed is:

1. A method of making graphene on a diamond substrate, comprising:
applying a layer of a metal to a crystallographic face of a diamond substrate; and
heating the diamond substrate under vacuum to convert a portion of the diamond substrate at the crystallographic face into graphene.

2. The method of claim 1, wherein the layer of metal is applied only on diamond substrate faces having a same crystallographic orientation.

3. The method of claim 1, wherein the layer of metal is applied to only a single crystallographic face of the diamond substrate.

4. The method of claim 1, further comprising removing the graphene from the diamond substrate.

5. The method of claim 1, wherein the crystallographic face is a (111) face.

6. The method of claim 1, wherein the diamond substrate is heated to a temperature of between about 600° C. and about 1400° C.

7. The method of claim 1, wherein the vacuum is from about 10⁻⁴ torr to about 10⁻⁶ torr.

8. The method of claim 1, wherein the layer of metal is a metal alloy.

9. The method of claim 8, wherein the metal alloy includes a member selected from the group consisting of Fe, Ni, Co, and combinations thereof.

10. The method of claim 9, wherein the metal alloy includes a member selected from the group consisting of Cu, Zn, and combinations thereof.

11. The method of claim 1, wherein converting the portion of the diamond substrate at the crystallographic face into graphene includes converting the portion of the diamond substrate by martensitic transformation.

12. The method of claim 1, wherein the diamond substrate is nanodiamond.

13. The method of claim 1, wherein an epitaxial relationship is maintained between the diamond substrate and the graphene.

14. The method of claim 13, further comprising heating the diamond substrate to a temperature of greater than or equal to about 700° C. in a hydrogen atmosphere to gasify non-epitaxial carbon atoms.

15. The method of claim 1, further comprising epitaxially depositing a semiconductor material on the graphene.

16. A diamond-graphene device, comprising:
a diamond substrate; and
a graphene material formed on and epitaxially aligned with a crystallographic surface of the diamond substrate, wherein the graphene material is oriented such that substantially all graphene planes are parallel to the crystallographic surface.

17. The device of claim 16, wherein the graphene material has been formed from a portion of the diamond substrate.

18. The device of claim 16, wherein the graphene material has been formed on a (111) face of the diamond substrate.

19. The device of claim 16, further comprising a semiconductor material epitaxially disposed on the graphene material.

20. The device of claim 16, wherein the semiconductor material includes a member selected from the group consisting of silicon, silicon carbide, silicon germanium, gallium arsenide, gallium nitride, germanium, zinc sulfide, gallium phosphide, gallium antimonide, gallium indium arsenide phosphide, aluminum phosphide, aluminum arsenide, aluminum gallium arsenide, gallium nitride, boron nitride, aluminum nitride, indium arsenide, indium phosphide, indium antimonide, indium nitride, and composites thereof.

21. The device of claim 16, wherein the semiconductor material includes a member selected from the group consisting of gallium nitride, aluminum nitride, indium nitride, and composites thereof.

22. The device of claim 16 incorporated into a device selected from the group consisting of, molecule sensors, LEDs, LCDs, solar panels, pressure sensors, SAW filters, resonators, and combinations thereof.

23. A diamond-graphene device made by the method of claim 1.

24. A method of making graphene on a diamond substrate, comprising:
heating a diamond substrate under vacuum in a hydrogen atmosphere to convert a portion of the diamond substrate at a (100) crystallographic face into graphene.
